(19) United States
(12) Patent Application Publication
(10) Pub. No.: US 2026/0371521 A1
(43) Pub. Date: Nov. 19, 2026

(54) MULTILAYER COOLING ASSEMBLIES HAVING MICROSTRUCTURES

(71) Applicant: Toyota Motor Engineering & Manufacturing North America, Inc., Plano, TX (US)

(72) Inventors: Danny J. Lohan, West Bloomfield, MI (US); Ercan Mehmet Dede, Ann Arbor, MI (US)

(73) Assignee: Toyota Motor Engineering & Manufacturing North America, Inc., Plano, TX (US)

(21) Appl. No.: 19/209,211

(22) Filed: May 15, 2025

(51) Int. Cl. H05K 7/20

(52) U.S. Cl. CPC H05K 7/20272

(57) ABSTRACT

In one embodiment, a cooling assembly includes an inlet for receiving a cooling fluid and an outlet. The cooling assembly also includes a plurality of layers, where the plurality of layers define at least one channel fluidly coupled to the inlet and the outlet, and operable to receive the cooling fluid. The plurality of layers also includes at least one microstructure fluidly coupled to the at least one channel. The at least one microstructure includes a plurality of microchannels, where a size of the plurality of microchannels is non-linearly graded in three dimensions.

### BACKGROUND

Liquid cooling devices may include a cold plate having internal channels through which a cooling fluid flows and absorbs heat from a heat-generating device, such as an electronics device. Optimization techniques have been used to design channels that provide as much heat removal as possible. For example, material property relaxation in finite element analysis methods have been used to generate new topological features. Optimization techniques may, given a microstructure shape which contains a void, increase or decrease the size of the void as the optimizer routine deems necessary. However, in the case of fluid flow physics, simple voids, or grids, create disconnected regions which inhibit fluid flow between finite elements. Additionally, present homogenization techniques of topology optimization bias properties towards solid or void obtains results which are more manufacturable, but these designs deviate from global optimal solutions when intermediate microstructures are penalized.

### BRIEF SUMMARY

In one embodiment, a cooling assembly includes an inlet for receiving a cooling fluid and an outlet. The cooling assembly also includes a plurality of layers, where the plurality of layers define at least one channel fluidly coupled to the inlet and the outlet, and operable to receive the cooling fluid. The plurality of layers also includes at least one microstructure fluidly coupled to the at least one channel. The at least one microstructure includes a plurality of microchannels, where a size of the plurality of microchannels is non-linearly graded in three dimensions.

In another embodiment, an electronics device assembly includes a cooling assembly and an electronic device coupled to a surface of the cooling assembly. The cooling assembly includes an inlet for receiving a cooling fluid and an outlet. The cooling assembly also includes a plurality of layers, where the plurality of layers define at least one channel fluidly coupled to the inlet and the outlet, and operable to receive the cooling fluid. The plurality of layers also includes at least one microstructure fluidly coupled to the at least one channel. The at least one microstructure includes a plurality of microchannels, where a size of the plurality of microchannels is non-linearly graded in three dimensions.

These and additional features provided by the embodiments described herein will be more fully understood in view of the following detailed description, in conjunction with the drawings.

### BRIEF DESCRIPTION OF THE SEVERAL VIEWS OF THE DRAWINGS

FIG. 1 illustrates a perspective view of an example electronics assembly according to one or more embodiments described and illustrated herein.

FIG. 2 illustrates a partial perspective view of an example cooling assembly according to one or more embodiments described and illustrated herein.

FIG. 3 graphically illustrates varying a thickness of features of layers of a cooling assembly according to one or more embodiments described and illustrated herein.

FIG. 4A illustrates an example layer of a cooling assembly having features oriented in a first direction according to one or more embodiments described and illustrated herein.

FIG. 4B illustrates an example layer of a cooling assembly having features oriented in a second direction according to one or more embodiments described and illustrated herein.

FIG. 4C illustrates a stack of the example layer of FIG. 4A and the example layer of FIG. 4B according to one or more embodiments described and illustrated herein.

FIG. 5A illustrates an exploded perspective view of a plurality of layers having orthogonal features in an example stack according to one or more embodiments described and illustrated herein.

FIG. 5B illustrates an exploded perspective view of a plurality of layers having orthogonal features in another example stack according to one or more embodiments described and illustrated herein.

FIG. 6 illustrates an exploded perspective view of a single unit cell having a plurality of layers according to one or more embodiments described and illustrated herein.

FIG. 7 illustrates an exploded perspective view of an example cooling assembly having a plurality of layers according to one or more embodiments described and illustrated herein.

FIG. 8 illustrates a cutaway perspective view of another example cooling assembly according to one or more embodiments described and illustrated herein.

FIG. 9 illustrates a partial top view of the example cooling assembly of FIG. 8 according to one or more embodiments described and illustrated herein.

### DETAILED DESCRIPTION

Embodiments of the present disclosure are directed to multilayer cooling assemblies having an interconnected microchannel network with a porosity that is non-linearly graded in three dimensions. The cooling assemblies described herein are highly manufacturable, and avoid disconnection between unit cells. More particularly, to obtain a direct and physical realization of a homogenized solution, embodiments employ the use of bonding technology (e.g., diffusion bonding) to bond multiple layers together to construct the homogenized solution. In one example, for a first layer an optimal homogenized solution is used to adjust a thickness of a vertical bar in unit cells across the domain. For a second layer, the same homogenized solution is used to adjust the thickness of horizontal bars across the domain. When stacked together, these two (or more) layers re-create the original porous microstructure for a given finite element while preserving connectivity between unit cells. This allows fluid flow to be biased toward emptier regions, while still flowing through the entire structure. Thus, embodiments start with an original porous microstructure assumption for a given optimized solution, and then use the features of multiple stacked layers to substantially recreate the original porous microstructure while maintaining interconnectedness between unit cells (i.e., between microchannels defined by the unit cells) while also doing so in a manner that is easy to manufacture the original porous microstructure.

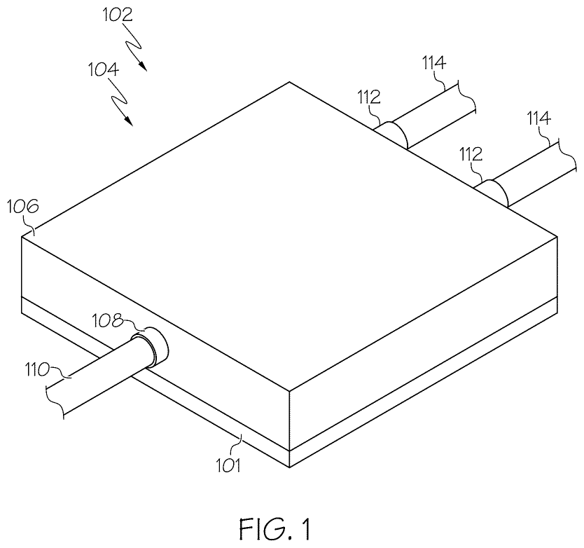

Referring now to FIG. 1, a non-limiting example of an electronics assembly 102 according to one or more embodiments is disclosed. The example electronics assembly 102 generally comprises a cooling assembly 104 and a heat-generating component 101. The cooling assembly 104 is operable to remove heat from the heat-generating component 101 by the use of a cooling fluid passing through the cooling assembly 104. Embodiments are not limited by the type of heat-generating component 101. As a non-limiting example, the heat-generating component 101 may be an electronics device, such as a power electronics device. For example, the electronics device may a be a power switching device used in electric motor applications, such as battery electric vehicle (BEV), plug-in hybrid electric vehicles (PHEV) and hybrid vehicles. The power switching device may be included in an inverter circuit that converts the direct current (DC) voltage of the battery to alternating current (AC) voltage that is applied to the electric motor to cause rotation of the electric motor. Non-limiting examples of power switching devices include insulated-gate bi-polar transistors (IGBT), metal-oxide-silicon field-effect transistors (MOSFET), silicon coated rectifiers (SCR), thyristors, transistors and any other electronics device capable of switching voltage. The electronics devices described herein may be fabricated from materials such as, without limitation, silicon (Si), gallium nitride (GaN), and silicon carbide (SiC).

The heat-generating component 101 may be attached to the cooling assembly 104 in any manner, such as by thermal paste, mechanical clamping, soldering, and brazing. Low thermal resistance between the heat-generating component 101 and a surface of the cooling assembly 104 provides for efficient heat transfer from the cooling fluid within the 104 to the heat-generating component.

The example cooling assembly 104 comprises a housing 1060 and an inlet 108 at a first end. An inlet fluid line 110 is fluidly coupled to the 108. The inlet fluid line 110 is fluidly coupled to a cooling fluid reservoir (not shown) such that cooling fluid is introduced to the inlet 108 from the cooling fluid reservoir. Cooling fluid flows along a first, primary direction (i.e., the Y-axis direction) as well as along a second, secondary direction (i.e., the X-axis direction). When the cooling fluid reaches a second end of the cooling assembly 104 along the first direction, it exits the cooling assembly 104 through an outlet 112. An outlet fluid line 114 is fluidly coupled to the outlet 112. The outlet fluid line 114 transports the cooling fluid to a heat exchanger (not shown) that cools the cooling fluid such that it may be returned to the cooling fluid reservoir and once again introduced into the cooling assembly 104.

It should be understood that embodiments of the present disclosure are not limited to laterally flowing cooling fluid, and that in some embodiments, the primary direction for cooling fluid flow is along a vertical (i.e., Z-axis) direction. For example, the inlet 108 may be disposed on a top of the housing 106 and the outlet 112 may be disposed on a bottom of the housing 106.

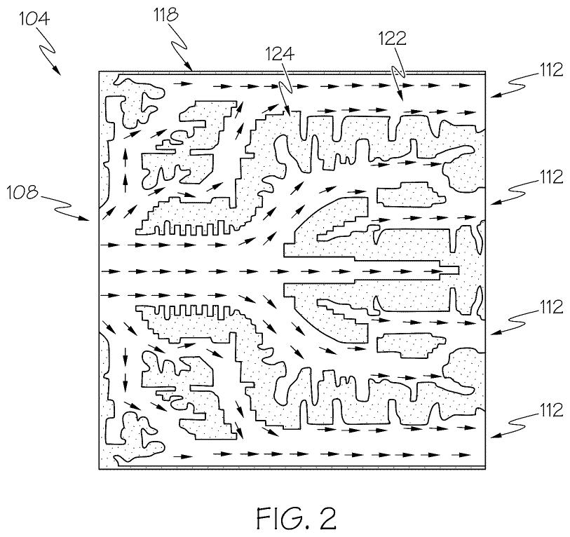

The cooling assembly 104 includes internal channels and microchannels through which cooling fluid flows, absorbing heat from the heat-generating component 101. Referring now to FIG. 2, cutaway view of an interior of an example cooling assembly 104. The example cooling assembly 104 has a manifold 118 that is disposed between the inlet 108 and the outlet 112. The manifold 118 includes a plurality of primary channels 122 and a plurality of microstructures 124. The plurality of primary channels 122 is defined by open spaces free of material that has the lowest flow resistance for cooling fluid entering the manifold 118 from the inlet 108. A majority of the cooling fluid will flow through the plurality of primary channels 122 due to the low flow resistance. It should be understood that although multiple branching primary channels 122 are shown in FIG. 2, a single primary channel may be provided depending on the design requirements. It should also be understood that embodiments are not limited to the primary channel design shown in FIG. 2 as FIG. 2 is provided for illustrative purposes only.

The plurality of microstructures 124 provides regions within the manifold 118 that include material that defines a plurality of microchannels. As the plurality of microstructures 124 include material, it increases the flow resistance for the cooling fluid. Therefore, a majority of cooling fluid will flow through the plurality of primary channels 122. However, some cooling fluid will enter the plurality of microchannels of the plurality of microstructures 124. The microchannels provide an increased surface area for heat transfer to the cooling fluid, as well increased surface area for nucleation in two-phase cooling applications.

Unlike traditional cooling assemblies, the size of the microchannels, also referred to as the porosity, is non-linearly graded in three dimensions. As described above, the design of the manifold including size and shape of the plurality of primary channels 122 and the plurality of microstructures 124, as well as the porosity of microchannels in three dimensions, may be produced by a topology optimization method. However, the resulting design of the topology optimization method may not be manufacturable, or it may be manufacturable but not at the scale needed for volume production. By using a stacked multi-layer approach, embodiments of the present disclosure enable the manufacture of a manifold design having a porosity that is non-linearly graded in three dimensions at scale.

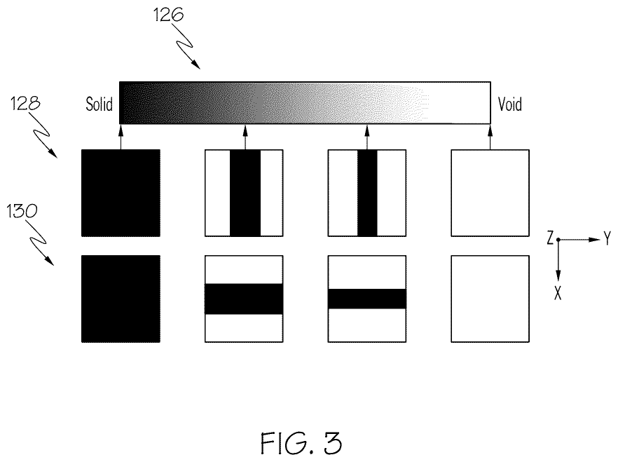

Referring now to FIG. 3, in some embodiments a graded material density is achieved by using stacked layers having features with varying thicknesses. The material density bar 126 illustrates a graded material density, with a solid on the far left-hand side and a pure void on the right-hand side. Each layer has features that are aligned with a single direction. The row of unit cells below the material density bar 126 are vertical features 128 that are aligned with a single direction along the X-axis. It should be understood that the term “vertical feature” is used for convenience and ease of description, and it not intended to mean that the feature must be in a vertical orientation. A thickness of the vertical features 128 is varied along a direction orthogonal to the vertical features 128 (i.e., a horizontal direction along the Y-axis). Each unit cell in FIG. 3 depicts a feature having a particular thickness. The left most vertical feature 128 has a maximum thickness to provide a solid material density. The thickness of the vertical features 128 decreases along the Y-axis until a unit cell has a vertical feature 128 with zero thickness, thereby providing a void.

The row of unit cells below the vertical features 128 illustrate horizontal features 130 that are aligned with a single direction along the Y-axis. It should be understood that the term “horizontal feature” is used for convenience and ease of description, and it not intended to mean that the feature must be in a horizontal orientation. A thickness of the horizontal features 130 is varied along a direction orthogonal to the horizontal features 130 (i.e., a vertical direction along the X-axis). The left most horizontal feature 130 has a maximum thickness to provide a solid material density. The thickness of the horizontal features 130 decreases along the Y-axis until a unit cell has a horizontal feature 130 with zero thickness, thereby providing a void.

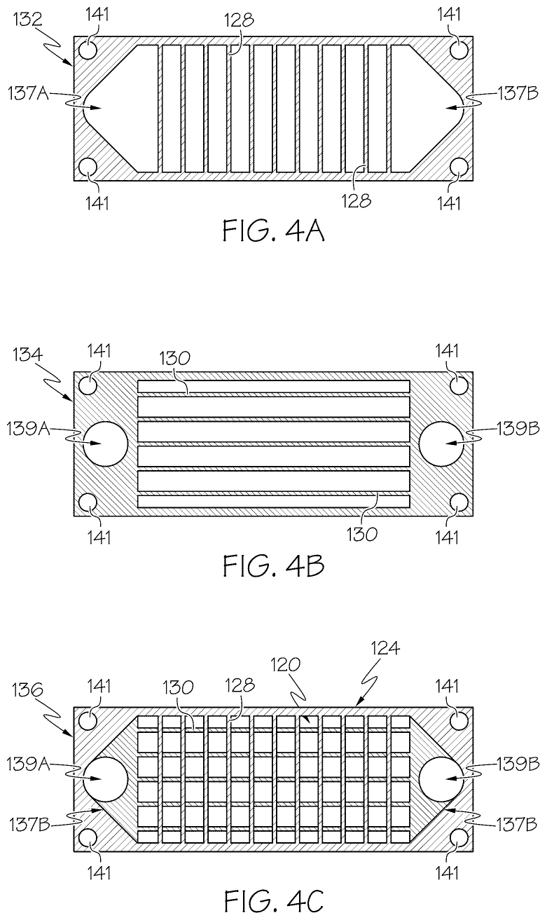

FIG. 4A illustrates an example first layer 132 having a plurality of vertical features 128. The thickness of the plurality of vertical features 128 may be non-linearly graded in a direction orthogonal to the vertical features 128 across the first layer 132. For example, the thickness of the plurality of vertical features 128 may be random across the first layer 132, or according to a design provided by a topology optimization method.

The example first layer 132 further includes an inlet channel 137A and an outlet channel 138B that are shaped to distribute cooling fluid toward and away from the plurality of vertical features, respectively.

The layers of the embodiments described herein may be fabricated from any thermally conductive material, such as, without limitation, metals (e.g., aluminum and copper) composite materials, polymers having thermally conductive filler particles, and graphite.

FIG. 4B illustrates an example second layer 134 having a plurality of horizontal features 130. The thickness of the plurality of horizontal features 130 may be non-linearly graded in a direction orthogonal to the horizontal features 130 across the second layer 134. For example, the thickness of the plurality of horizontal features 130 may be random across the second layer 134, or according to a design provided by a topology optimization method. The example second layer 134 further includes an inlet 139A and an outlet 139B to provide and remove cooling fluid from various layers, respectively.

FIG. 4C illustrates how the first layer 132 of FIG. 4A and the second layer 134 of FIG. 4B are stacked on one another to form stacked layers 136. The stacked layers 136 define a having an array of microchannels 120. Each microchannel 120 may be referred to as a unit cell, for example. The thicknesses of the vertical features 128 and the horizontal features 130 define a size of each microchannel in three dimensions along the X-axis, the Y-axis and the Z-axis. By manipulating the thicknesses of the vertical features 128 and the horizontal features 130, the porosity of the microstructure 124 can be non-linearly graded according to an optimized design.

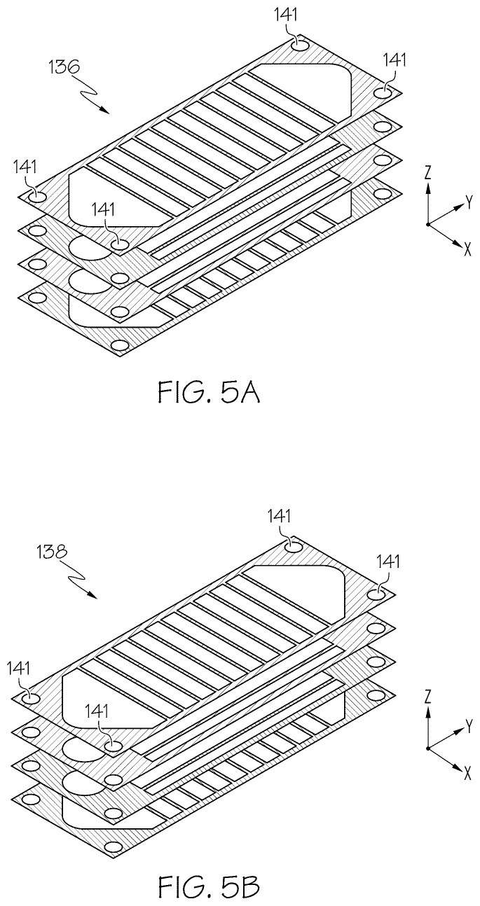

FIG. 5A illustrates a perspective view of an example microstructure defined by four layers having orthogonally alternating features. It should be understood that any number of layers may be utilized depending on the optimized design. The thicknesses of the orthogonally alternating features are varied along the X-, Y- and Z-axes to achieve a microstructure 124 with a desired non-linearly graded design. In some embodiments, a topology optimization program receives design constraints and produces a three-dimensional model representing the overall design. The topology optimization program, or another program, outputs the design of the individual layers that achieves the three-dimensional design. Thus, each layer can be individually manufactured easily (e.g., by molding, stamping, additive manufacturing, machining) and then stacked by an attachment method, such as adhesive, mechanical fasteners (e.g., through the screw holes 141 shown in FIGS. 4A-4C, 5A and 5B), thermal paste, soldering, brazing, and diffusion bonding, as non-limiting examples.

When stacked together, the layers re-create an original porous microstructure assumption for a given finite element while preserving connectivity between cells. This allows cooling fluid flow to be biased toward emptier regions, while still flowing through the entire structure. While FIGS. 4A-5B show a design in the in-plane direction, a similar strategy may be used to create flow structures in the through-plane direction.

FIG. 5B illustrates an example where stacked layers 138 include two adjacent layers having features oriented in the same direction. For example, the top two layers shown in FIG. 5B have features aligned along the X-axis while the bottom two layers shown in FIG. 5B have features aligned along the Y-axis. The use of two layers having features of the same orientation allow the height of segments of each microchannel to be increased. It should be understood that any number of layers of the stack may be included, as well as any number of adjacent layers having features with the same orientation.

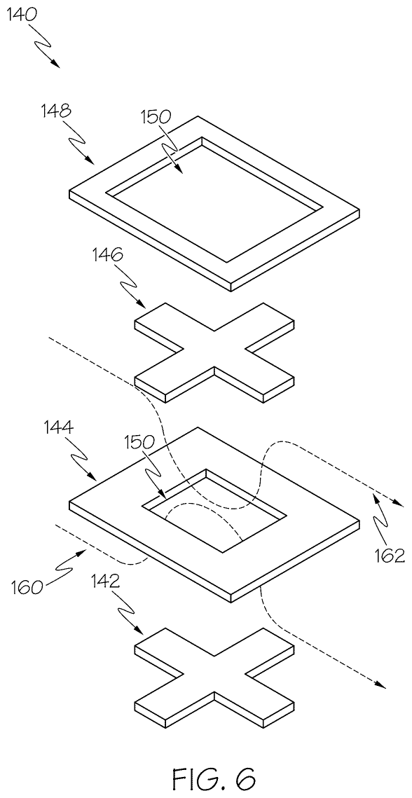

The methodology described above may also be extended to alternative shapes and meshes when using a template layer. Referring to FIG. 6, alternating opening layers and mesh layers are used to form unit cells that are varied in dimensions based on optimization results. FIG. 6 shows the layers as an individual unit cell 140 for ease of illustration. A first mesh layer 142, which is illustrated by the cross shape, is a mesh comprising repeating orthogonal members (i.e., orthogonal features). A thickness of the orthogonal members may be varied across the X- and Y-axes as described above to non-linearly vary a porosity of the resulting microstructure as described above.

A first opening layer 144 is attached to the first mesh layer 142. The first opening layer 144 has an array of openings 150. Although the opening 150 is illustrated as a square, embodiments are not limited thereto. The openings 150 may be circles, ellipses and any other shape, including arbitrary shapes. The shape of the openings 150 may be selected based on optimization results. A size of the openings 150 may be non-linearly varied across the first opening layer 144 depending on the optimized design. A second mesh layer 146 is attached to the first opening layer 144. Like the first mesh layer 142, the thickness of the orthogonal members may be varied across the X- and Y-axes to non-linearly vary a porosity of the resulting microstructure. The thickness profile of the second mesh layer 146 may be different than the thickness profile of the first mesh layer 142, for example. A second opening layer 148 is attached to the second mesh layer 146. Like the first opening layer 144, the size of the openings 150 may vary across the second opening layer 148. The size profile of the openings 150 of the first opening layer 144 may be different than the size profile of the openings 150 of the second opening layer 148, for example.

Any number of layers may be used in the stack according to the optimized design. Having different sized openings 150 across each of the first opening layer 144 and the second opening layer 148, as well as differing size profiles of the openings between the first opening layer 144 and the second opening layer 148 and varied thickness profiles across and between the first mesh layer 142 and the second mesh layer 146 enable a microstructure having a non-linearly graded porosity in three dimensions.

As shown in FIG. 6, cooling fluid 162 may flow through the porous semi-solid regions that define microchannels.

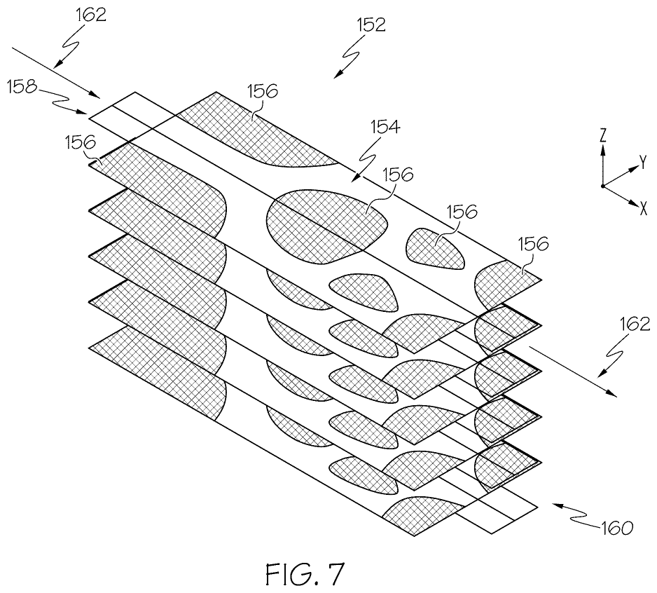

FIG. 7 illustrates an example stack 152 of layers of an example cooling assembly. Each layer of the stack 152 has open primary channels 154, the design of which results from an optimization process, such as a topology optimization process. The shapes of the open primary channels 154 are dictated by porous microstructures 156. The porosity of the microstructures 156 is non-linearly graded in three dimensions. As a non-limiting example, the microstructures 156 are fabricated by the mesh and opening layers illustrated by FIG. 6. The size of the openings 150 and thicknesses of the meshes are varied in three dimensions to provide the non-linearly graded porosity in three dimensions.

Cooling fluid 162 entering through the inlet 108 flows both through the open primary channels 122 globally at the macro-scale, as well as through the porous semi-solid region locally at the micro-scale, where it then exits the cooling assembly through the outlet 112.

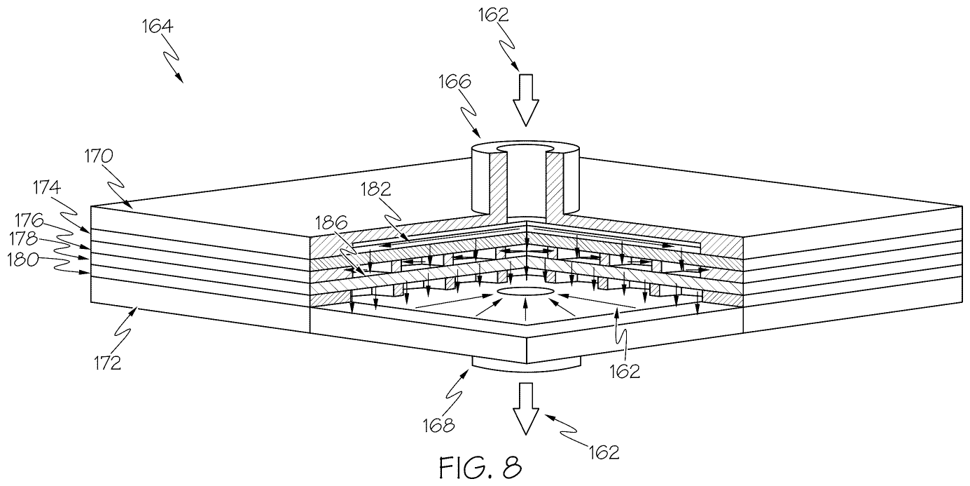

FIG. 8 illustrates a cutaway view of another example cooling assembly 164. The cooling assembly has an upper layer 170 having an inlet 166, a first opening layer 174, a first mesh layer 176, a second opening layer 178, a second mesh layer 180, and a lower layer 172 having an outlet 168. It is noted that the terms “upper” and “lower” are used for convenience and are not intended to limit the cooling assembly into any particular orientation. The first and second opening layers 174, 178 and the first and second mesh layers 176, 180 may be configured similarly to the first and second opening layers 144, 148 and the first and second mesh layers 142, 146 illustrated in FIG. 6, or may take on different configurations.

The bottom surface of the upper layer 170 includes a recess that provides a channel 182 acting as a cooling fluid distribution for cooling fluid 162 entering the cooling assembly 164 from the inlet 166. As shown by the arrows, the cooling fluid 162 spreads throughout the channel 182, and then flows down into microchannels 186 provided by the alternating openings and mesh structures of the first and second opening layers 174, 178 and the first and second mesh layers 176, 180. After flowing through the microchannels 186, the cooling fluid 162 flows toward a center of the lower layer 172 and exits through the outlet 168. The cooling fluid 162 may then be routed through a heat exchanger (not shown) to be cooled and then reintroduced to the cooling assembly 164 in a closed loop system.

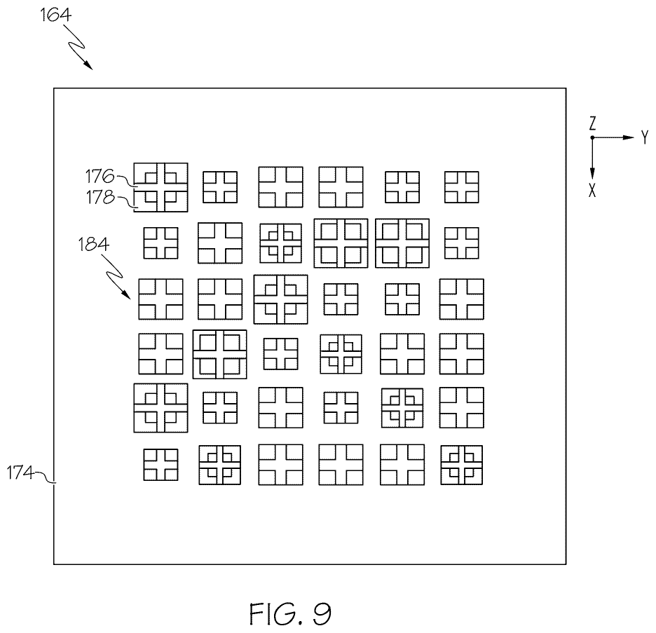

FIG. 9 illustrates a top view of the cooling assembly 164 of FIG. 8 without the upper layer 170. The configuration of the first and second opening layers 174, 178 and the first and second mesh layers 176, 180 may be varied in three dimensions to provide an array of unit cells 184 having different dimensions according to an optimized design. Thus, the porosity of the cooling assembly 164 is non-linearly graded in three dimensions. The cooling fluid 162 may travel through various hole sized through-plane and in-plane between the inlet 166 and the outlet 168.

Referring to the upper-left unit cell 184 of FIG. 9, the first opening within the first opening layer 174 is larger than the second opening of the second opening layer 178, providing a microchannel that narrows in a direction from the inlet 166 toward the outlet 160. On the other hand, the unit cell 184 to the right of the upper-left unit cell 184 has an opening within the first opening layer 174 that is either equal in size or smaller than the opening in the second opening layer 178. When the opening within the second opening layer 178 is larger than the opening in the first opening layer 174, the resulting microchannel widens in a direction from the inlet 166 to the outlet 160. It is also noted that the thickness of the first and second mesh layers 176, 180 may also be varied across the X- and Y-directions, and the thickness profile of first and second mesh layers 176, 180 may be different. In some embodiments, the thickness of the first and second mesh layers 176, 180 is uniform and not varied.

In embodiments of the present disclosure, an optimization method is used to produce a cooling assembly having an optimized design according to design constraints. The optimization method may output individual layers that, when stacked and bonded to one another (e.g., by a diffusion bonding process), produce the overall optimized design, while maintaining interconnectedness between all of the microchannels of a microstructure. The optimized design may include macro-channels as well as microstructures with microchannels having a porosity that is non-linearly graded in three dimensions. Use of the layering process allows large-volume manufacturing of designs that are not easily manufacturable.

It is noted that the terms “substantially” and “about” and “approximately” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. A cooling assembly comprising:
an inlet for receiving a cooling fluid;
an outlet; and
a plurality of layers, wherein the plurality of layers define:
at least one channel fluidly coupled to the inlet and the outlet, and operable to receive the cooling fluid; and
at least one microstructure fluidly coupled to the at least one channel and comprising a plurality of microchannels, wherein a porosity of the plurality of microchannels is non-linearly graded in three dimensions.

2. The cooling assembly of claim 1, wherein the plurality of layers comprises orthogonally alternating features having a thickness that is varied in a first direction or a second direction such that the orthogonally alternating features define the plurality of microchannels.

3. The cooling assembly of claim 2, wherein the orthogonally alternating features define an array of unit cells, wherein a size of an opening of each unit cell varies in a third direction.

4. The cooling assembly of claim 3, wherein the size of the openings of the array of unit cells also vary in the first direction and the second direction.

5. The cooling assembly of claim 1, wherein the plurality of layers comprises:
a first mesh layer;
a first opening layer adjacent the first mesh layer, the first opening layer comprising a first plurality of openings;
a second mesh layer adjacent the first opening layer; and
a second opening layer adjacent the second mesh layer, the second opening layer comprising a second plurality of openings, wherein the second plurality of openings is aligned with the first plurality of openings such that the first mesh layer, the first opening layer, the second mesh layer, and the second opening layer define the plurality of microchannels.

6. The cooling assembly of claim 5, a thickness of the first mesh layer and a thickness of the second mesh layer are varied in three dimensions, and a size of individual first openings of the first plurality of openings and a size of individual second openings of the second plurality of openings are varied in three dimensions.

7. The cooling assembly of claim 5, wherein the plurality of layers further comprises an inlet layer comprising the inlet and an outlet layer comprising the outlet.

8. The cooling assembly of claim 7, wherein the inlet layer defines the at least one channel.

9. The cooling assembly of claim 1, wherein the inlet is provided at a first end of the plurality of layers and the outlet is provided at a second end of the plurality of layers.

10. An electronics device assembly comprising:
a cooling assembly comprising:
an inlet for receiving a cooling fluid;
an outlet; and
a plurality of layers, wherein the plurality of layers define:
at least one channel fluidly coupled to the inlet and the outlet, and operable to receive the cooling fluid; and
at least one microstructure fluidly coupled to the at least one channel and comprising a plurality of microchannels, wherein a porosity of the plurality of microchannels is non-linearly graded in three dimensions; and
an electronics device coupled to a surface of the cooling assembly.

11. The electronics device assembly of claim 10, wherein the plurality of layers comprises orthogonally alternating features having a thickness that is varied in a first direction or a second direction such that the orthogonally alternating features define the plurality of microchannels.

12. The electronics device assembly of claim 11, wherein the orthogonally alternating features define an array of unit cells, wherein a size of an opening of each unit cell varies in a third direction.

13. The electronics device assembly of claim 12, wherein the size of the openings of the array of unit cells also vary in the first direction and the second direction.

14. The electronics device assembly of claim 10, wherein the plurality of layers comprises:
a first mesh layer;
a first opening layer adjacent the first mesh layer, the first opening layer comprising a first plurality of openings;
a second mesh layer adjacent the first opening layer; and
a second opening layer adjacent the second mesh layer, the second opening layer comprising a second plurality of openings, wherein the second plurality of openings is aligned with the first plurality of openings such that the first mesh layer, the first opening layer, the second mesh layer, and the second opening layer define the plurality of microchannels.

15. The electronics device assembly of claim 14, a thickness of the first mesh layer and a thickness of the second mesh layer are varied in three dimensions, and a size of individual first openings of the first plurality of openings and a size of individual second openings of the second plurality of openings are varied in three dimensions.

16. The electronics device assembly of claim 14, wherein the plurality of layers further comprises an inlet layer comprising the inlet and an outlet layer comprising the outlet, and the electronics device is coupled to the outlet layer.

17. The electronics device assembly of claim 16, wherein the inlet layer defines the at least one channel.

18. A method of manufacturing a cooling assembly, the method comprising:
receiving one or more first layers comprising at least one first channel and a plurality of first features;
receiving one or more second layers comprising at least one second channel and a plurality of second features;
alternately arranging the one or more first layers and the one or more second layers;
securing the one or more first layers and the one or more second layers into a stack such that the plurality of first features and the plurality of second features define at least one microstructure comprising a plurality of microchannels, wherein a size of the plurality of microchannels is non-linearly graded in three dimensions by the plurality of first features and the plurality of second features of the one or more first layers and the one or more second layers, respectively.

19. The method of claim 18, wherein the stack reflects an optimized design outputted by a topology optimization program.

20. The method of claim 19, wherein the topology optimization program outputs designs of the one or more first layers and the one or more second layers that define the optimized design.
